(19) United States
(12) Patent Application Publication
(10) Pub. No.: US 2025/0221163 A1
(43) Pub. Date: Jul. 3, 2025

(54) Display Device

(71) Applicant: LG Display Co., Ltd., Seoul (KR)

(72) Inventors: Eunhyung Lee, Paju-si (KR); Youngchul Shin, Paju-si (KR)

(21) Appl. No.: 18/908,217

(22) Filed: Oct. 7, 2024

(30) Foreign Application Priority Data
Dec. 28, 2023 (KR) 10-2023-0195629

(51) Int. Cl. H10K 59/121; H10K 59/13; H10K 101/00; H10K 101/10; H10K 101/40

(52) U.S. Cl. CPC H10K 59/121; H10K 59/13; H10K 2101/10; H10K 2101/40; H10K 2101/90

(57) ABSTRACT

A display device presented herein includes a first emission layer including a first host in an optical area where low-resolution pixels are disposed, and a second emission layer including a second host different from the first host. The display device is capable of reducing a difference in luminance between an area where the low-resolution pixels are disposed and an area where high-resolution pixels are disposed.

### CROSS-REFERENCE TO RELATED APPLICATION

This application claims the priority from Republic of Korea Patent Application No. 10-2023-0195629, filed on Dec. 28, 2023, which is hereby incorporated by reference in its entirety.

### BACKGROUND

### Field

The present disclosure relates to electronic devices with displays, and more specifically, to display devices.

### Description of Related Art

As display technology has been developed to provide increased functions, display devices can provide an image capturing function, a sensing function, and the like, as well as an image display function.

To provide these functions, display devices may need to include an optical electronic device, such as a light receiving device, a camera, a sensor for detecting an image, and the like.

In order to receive light passing through the front surface of display devices, it may be desirable for such an optical electronic device to be located in an area of the display devices where incident light coming from the front surface can be increasingly received and detected.

To achieve the foregoing, in display devices, an optical electronic device has been designed to be located in a front portion of the display devices to allow a camera, a sensor, and/or the like as the optical electronic device to be increasingly exposed to incident light.

In order to install an optical electronic device in display devices in this manner, a bezel area of the display devices may be increased, or a notch or a hole may be needed to be formed in a display area of an associated display panel.

Accordingly, it may be desirable that the display devices have higher transmittance to perform intended functions even when the optical electronic device, such as the camera, the sensor, and/or the like, that receives or detects incident light, and performs a predefined function is attached to the display devices.

### SUMMARY

To realize full screen in a display device, there may be provided a scheme of assigning an area for disposing low-resolution pixels in a screen area of a display panel, and disposing a camera and/or various sensors in an area of the display device that is located under the display panel and opposite to the area where the low-resolution pixels are disposed.

However, since pixels are still present in the area where the low-resolution pixels are disposed, and corresponding light emitting areas become reduced, more than 1.5 times current needed for driving the low-resolution pixels may be required to maintain the same luminance.

As an amount of required current increases, the lifetime of the pixels may be reduced. Thereby, as time passes, a difference in luminance between the area where the low-resolution pixels are disposed and an area where high-resolution pixels are disposed may become great, and in turn, a boundary of the area where the low-resolution pixels are disposed may be clearly recognized.

To address these issues, embodiments of the present disclosure are directed to a display device capable of reducing a difference in luminance between an area where low-resolution pixels are disposed and an area where high-resolution pixels are disposed even when the low-resolution pixels are used for a long time by increasing the lifetime of the low-resolution pixels.

One or more embodiments of the present disclosure may provide a display device capable of reducing a difference in luminance between an area where low-resolution pixels are disposed and an area where high-resolution pixels are disposed.

According to one or more embodiments of the present disclosure, a display device can be provided that includes a substrate including a normal area with a plurality of first pixels in the normal area and the normal area having a first resolution, and an optical area with a plurality of second pixels in the optical area and the optical area having a second resolution that is less than the first resolution, a first electrode layer on the substrate, a first emission layer on the first electrode layer, the first emission layer including a first host in the normal area and a first host in the optical area, a second emission layer on the first emission layer, the second emission layer including the first host in the normal area and a second host, the second host different from the first host in the optical area, and a second electrode layer on the second emission layer.

According to one or more embodiments of the present disclosure, a display device may comprise a normal area including a plurality of first subpixels; and an optical area including a plurality of second subpixels, wherein a number of the plurality of second subpixels per unit area in the optical area is less than a number of the plurality of first subpixels per unit area in the normal area, wherein each of the plurality of first subpixels in the normal area and the plurality of second subpixels in the optical area comprises a light emitting element, wherein the light emitting element comprises: a first electrode layer on a substrate; one or more stacks; and a second electrode layer on the one or more stacks, wherein each of the one or more stacks comprises: a first emission layer on the first electrode layer, the first emission layer comprising a first host in the normal area and a first host in the optical area; and a second emission layer on the first emission layer, the second emission layer comprising the first host in the normal area and a second host, the second host different from the first host in the optical area.

According to one or more embodiments of the present disclosure, a display device may be provided that is capable of reducing a difference in luminance between an area where low-resolution pixels are disposed and an area where high-resolution pixels are disposed, and thereby, enabling low power operation.

### BRIEF DESCRIPTION OF THE DRAWINGS

The accompanying drawings, which are included to provide a further understanding of the disclosure and are incorporated in and constitute a part of the disclosure, illustrate embodiments of the disclosure and together with the description serve to explain principles of the disclosure. In the drawings:

FIG. 1 is a plan view of an example display device according to one or more embodiments of the present disclosure;

FIG. 2 illustrates an example system configuration of the display device according to one or more embodiments of the present disclosure;

FIG. 3 illustrates an example equivalent circuit of a subpixel in a display panel according to one or more embodiments of the present disclosure;

FIG. 4 illustrates arrangements of subpixels in example three areas included in a display area of the display device according to one or more embodiments of the present disclosure;

FIGS. 5 and 6 are cross-sectional views of example light emitting elements included in the display device according to one or more embodiments of the present disclosure;

FIGS. 7A and 7B are cross-sectional views of example light emitting elements disposed in a normal area and an optical area of the display device according to one or more embodiments of the present disclosure;

FIGS. 8A to 8C illustrate triple state energy levels of example light emitting elements included in the display device according to one or more embodiments of the present disclosure;

FIGS. 9A to 9D are graphs showing the results of evaluation for an example light emitting element manufactured according to one or more embodiments of the present disclosure; and

FIGS. 10A to 10D are graphs showing the results of evaluation for another light emitting element manufactured according to one or more embodiments of the present disclosure.

### DETAILED DESCRIPTION

Reference will now be made in detail to embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure embodiments of the present disclosure, a detailed description of such known function or configuration may be omitted. The shapes, sizes, ratios, angles, numbers, and the like, which are illustrated in the drawings to describe various embodiments of the present disclosure, are merely given by way of example. Therefore, the present disclosure is not limited to the illustrations in the drawings. Where the terms “comprise,” “have,” “include,” “comprise,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” “A”, “B”, “(a)”, “(b)”, and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, with reference to the accompanying drawings, various embodiments of the present disclosure will be described in detail.

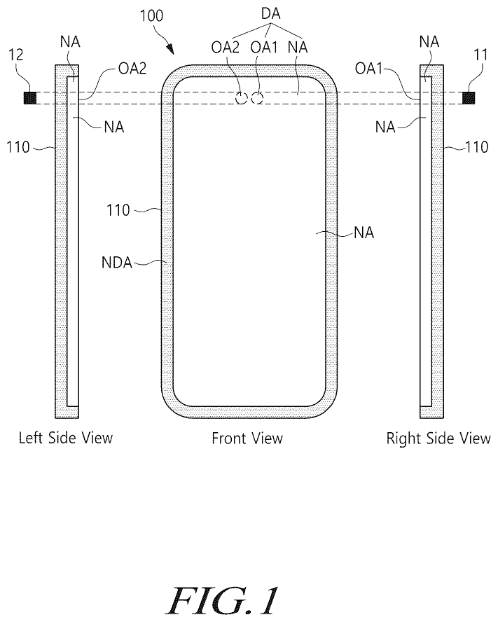

FIG. 1 is a plan view of an example display device 100 according to one or more embodiments of the present disclosure.

Referring to FIG. 1, in one or more embodiments, the display device 100 may include a display panel 110 for displaying an image, and one or more optical electronic devices (11 and/or 12). Herein, an optical electronic device may be referred to as a light detector, a light receiver, or a light sensing device. An optical electronic device may include one or more of a camera, a camera lens, a sensor, a sensor for detecting images, or the like.

The display panel 110 may include a display area DA configured to allow one or more images to be displayed and a non-display area NDA in which an image is not displayed.

A plurality of subpixels may be disposed in the display area DA, and several types of signal lines for driving the plurality of subpixels may be disposed therein.

The non-display area NDA may refer to an area outside of the display area DA.

Several types of signal lines may be disposed in the non-display area NDA, and several types of driving circuits can be connected thereto.

At least a portion of the non-display area NDA may be bent to be invisible from the front surface of the display device 100 or may be covered by a case or housing (not shown) of the display device 100.

The non-display area NDA may be also referred to as a bezel or a bezel area.

Referring to FIG. 1, in one or more embodiments, the one or more optical electronic devices (11 and/or 12) included in the display device 100 may be located under, or in a lower portion of, the display panel 110 (an opposite side to the viewing surface thereof).

Light can enter the front surface (the viewing surface) of the display panel 110, pass through the display panel 110, reach one or more optical electronic devices (11 and/or 12) located under, or in the lower portion of, the display panel 110 (the opposite side of the viewing surface).

The one or more optical electronic devices (11 and/or 12) may be devices capable of receiving or detecting light passing through the display panel 110 and perform a predefined function based on the received light.

For example, the one or more optical electronic devices (11 and/or 12) may include one or more of the following: an image capture device such as a camera (an image sensor), and/or the like; or a sensor such as a proximity sensor, an illuminance sensor, and/or the like.

For example, the illuminance sensor may be an ambient light sensor, but embodiments of the present disclosure are not limited thereto.

In a state where the display device 100 is turned off, the display device 100 can detect ambient light using the illuminance sensor, and adjust the luminance of an image on a screen displayed through the display panel 110 based on the brightness of the ambient light.

Referring to FIG. 1, in one or more embodiments, the display area DA defined in the display panel 100 may include a normal area NA and one or more optical areas (OA1 and/or OA2). Herein, the term “normal area” NA may be an area that while being present in the display area DA, does not overlap with one or more optical electronic devices (11 and/or 12). The normal area NA may also be referred to as a non-optical area.

Referring to FIG. 1, the one or more optical areas (OA1 and/or OA2) may be one or more areas respectively overlapping with the one or more optical electronic devices (11 and/or 12).

According to the example of FIG. 1, the display area DA may include a normal area NA, a first optical area OA1, and a second optical area OA2.

In the example of FIG. 1, a portion of the normal area NA may be present between the first optical area OA1 and the second optical area OA2.

Although FIG. 1 illustrates a structure in which each of the first and second optical area (OA1 and OA2) has a circular shape, respective shapes of the first and second optical area (OA1 and OA2) according to embodiments of the present disclosure are not limited thereto.

In one or more embodiments, the first optical area OA1 may have various shapes, such as a circle, an ellipse, a quadrangle, a hexagon, an octagon or the like.

In one or more embodiments, the second optical area OA2 may have various shapes, such as a circle, an ellipse, a quadrangle, a hexagon, an octagon or the like.

The first optical area OA1 and the second optical area OA2 may have the same or substantially or nearly the same shape, or different shapes.

Hereinafter, for convenience of description, discussions are provided based on examples where each of the first optical area OA1 and the second optical area OA2 has a circular shape. It should be, however, understood that the scope of the present disclosure includes examples where at least one of the first optical area OA1 and the second optical area OA2 has a shape other than the circular shape.

In this example, at least a portion of the first optical area OA1 may overlap with the first optical electronic device 11, and at least a portion of the second optical area OA2 may overlap with the second optical electronic device 12.

In one or more embodiments, the one or more optical areas (OA1 and/or OA2) included in the display panel 110 or the display device 100 are needed to be configured with both an image display structure and a light transmissive structure.

For example, since the one or more optical areas (OA1 and/or OA2) are respective portions of the display area DA, therefore, it is desirable that subpixels for displaying images are disposed in the one or more optical areas (OA1 and/or OA2).

Further, to enable light entering the display panel 110 or the display device 100 to reach the one or more optical electronic devices (11 and/or 12), it is also desirable that each of the one or more optical areas (OA1 and/or OA2) is configured with a light transmissive structure.

It should be noted that even though the one or more optical electronic devices (11 and/or 12) are devices that need to receive light, the one or more optical electronic devices (11 and/or 12) may be located on the back of the display panel 110 (e.g., on an opposite side of the viewing surface thereof). Therefore, the one or more optical electronic devices (11 and/or 12) can receive light that has passed through the display panel 110.

For example, the one or more optical electronic devices (11 and/or 12) may not be exposed in the front surface (viewing surface) of the display panel 110 or the display device 100.

Accordingly, when a user views the front surface of the display device 110, the one or more optical electronic devices (11 and/or 12) are located so that they cannot be visible to the user.

The first optical electronic device 11 may be, for example, a camera, and the second optical electronic device 12 may be, for example, a sensor. The sensor may be a proximity sensor, an illuminance sensor, an infrared sensor, and/or the like.

In one or more embodiments, the camera may be a camera lens, an image sensor, or a unit including at least one of the camera lens and the image sensor, and the sensor may be an infrared sensor capable of detecting infrared light.

In one or more embodiments, the first optical electronic device 11 may be a sensor, and the second optical electronic device 12 may be a camera.

Hereinafter, for convenience of description, discussions are provided based on examples where the first optical electronic device 11 is a camera, and the second optical electronic device 12 is a sensor. It should be, however, understood that the scope of the present disclosure includes examples where the first optical electronic device 11 is the sensor, and the second optical electronic device 12 is the camera.

The camera may be, for example, a camera lens, an image sensor, or a unit including at least one of the camera lens and the image sensor.

In an example where the first optical electronic device 11 is a camera, this camera may be located on the back of (e.g., under, or in a lower portion of) the display panel 110, and be a front camera capable of capturing objects or images in a front direction of the display panel 110.

Accordingly, the user can capture an image or object through the camera that is invisible on the viewing surface while looking at the viewing surface of the display panel 110.

Although the normal area NA and the one or more optical areas (OA1 and/or OA2) included in the display area DA are areas configured to allow images to be displayed, the normal area NA may be an area where a light transmissive structure need not be implemented, but the one or more optical areas (OA1 and/or OA2) may be areas where a light transmissive structure need be implemented. Thus, in one or more embodiments, the normal area NA may be an area where a light transmissive structure is not implemented or included, and the one or more optical areas (OA1 and/or OA2) may be areas in which a light transmissive structure is implemented or included.

Accordingly, the one or more optical areas (OA1 and/or OA2) may have a transmittance greater than or equal to a predetermined level, i.e., a relatively high transmittance, and the normal area NA may have a transmittance less than the predetermined level or not have light transmittance.

For example, the one or more optical areas (OA1 and/or OA2) may have a resolution, a subpixel arrangement structure, a number of subpixels per unit area, an electrode structure, a line structure, an electrode arrangement structure, a line arrangement structure, and/or the like different from that/those of the normal area NA.

For example, the number of subpixels per unit area in the one or more optical areas (OA1 and/or OA2) may be less than the number of subpixels per unit area in the normal area NA.

For example, the resolution of the one or more optical areas (OA1 and/or OA2) may be lower than that of the normal area NA.

Here, the number of subpixels per unit area may be a unit for measuring resolution, for example, referred to as pixels (or subpixels) per inch (PPI), which represents the number of pixels (or subpixels) within 1 inch.

For example, the number of subpixels per unit area in the first optical areas OA1 may be less than the number of subpixels per unit area in the normal area NA.

For example, the number of subpixels per unit area in the second optical areas OA2 may be greater than or equal to the number of subpixels per unit area in the first optical areas OA1.

Herein, in examples where the display device 100 has a structure in which the first optical electronic device 11 such as a camera, and the like, is located under, or in a lower portion of, the display panel 100 without being exposed to the outside, such a display device 100 may be referred to as a display in which under-display camera (UDC) technology is applied.

According to these examples, the display device 100 can have an advantage of avoiding the size reduction of the display area DA because a notch or a camera hole for exposing a camera need not be formed in the display panel 110.

Indeed, since a notch or a camera hole for camera exposure need not be formed in the display panel 110, the display device 100 can provide further advantages of reducing the size of a bezel area, and improving the degree of freedom in design because such limitations to the design are removed.

Although the one or more optical electronic devices (11 and/or 12) are located on the back of (e.g., under, or in a lower portion of) the display panel 110 of the display device 100 (e.g., hidden or not to be exposed to the outside), the one or more optical electronic devices (11 and/or 12) are needed to perform predefined functionalities by normally receiving or detecting light.

Further, in the display device 100, although one or more optical electronic devices (11 and/or 12) are located on the back of (e.g., under, or in a lower portion of) the display panel 110 to be hidden and located to be overlap with the display area DA, it is necessary for image display to be normally performed in the one or more optical areas (OA1 and/or OA2) overlapping with the one or more optical electronic devices (11 and/or 12) in the display area DA. Thus, in one or more examples, even though one or more optical electronic devices (11 and/or 12) are located on the back of the display panel, images can be displayed in a normal manner (e.g., without reduction in image quality) in the one or more optical areas (OA1 and/or OA2) overlapping with the one or more optical electronic devices (11 and/or 12) in the display area DA.

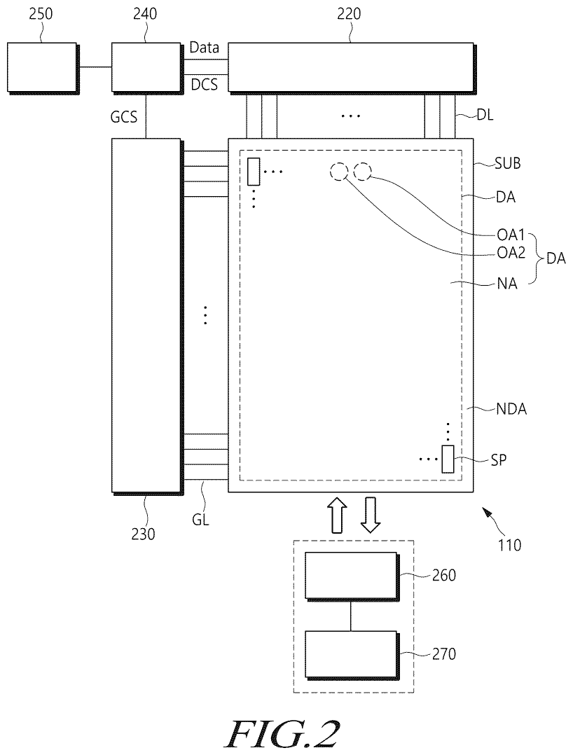

FIG. 2 illustrates an example system configuration of the display device 100 according to one or more embodiments of the present disclosure.

Referring to FIG. 2, the display device 100 may include the display panel 110 and a display driving circuit as components for displaying one or more images.

The display driving circuit may be a circuit for driving the display panel 110, and include a data driving circuit 220, a gate driving circuit 230, a display controller 240, and other circuit components.

The display panel 110 may include a display area DA configured to allow one or more images to be displayed and a non-display area NDA in which an image is not displayed.

The non-display area NDA may be an area outside of the display area DA, and may also be referred to as an edge area or a bezel area.

All or a portion of the non-display area NDA may be an area visible from the front surface of the display device 100, or an area that is bent and invisible from the front surface of the display device 100.

The display panel 110 may include a substrate SUB and a plurality of subpixels SP disposed on the substrate SUB.

The display panel 110 may further include various types of signal lines to drive the plurality of subpixels SP.

In one or more embodiments, the display device 100 may be a liquid crystal display device, or the like, or a self-emission display device in which light is emitted from the display panel 210 itself.

In the example where the display device 100 is a self-emission display device, each of the plurality of subpixels SP may include a light emitting element.

For example, the display device 100 according to one or more embodiments of the present disclosure may be an organic light emitting display device in which light emitting elements ED are implemented using organic light emitting diodes (OLED).

In another example, the display device 100 according to embodiments of the present disclosure may be an inorganic light emitting display device in which light emitting elements are implemented using inorganic material-based light emitting diodes.

In further another example, the display device 100 according to one or more embodiments of the present disclosure may be a quantum dot display device implemented with quantum dots, which are self-emission semiconductor crystals, as light emitting elements.

The structure of each of the plurality of subpixels SP may be differently configured or designed according to types of the display devices 100.

In an example where the display device 100 is a self-emission display device including self-emission subpixels SP, each subpixel SP may include a self-emission light emitting element, one or more transistors, and one or more capacitors.

The various types of signal lines may include, for example, a plurality of data lines DL for carrying data signals (which may be referred to as data voltages or image signals), a plurality of gate lines GL for carrying gate signals (which may be referred to as scan signals), and the like.

The plurality of data lines DL and the plurality of gate lines GL may intersect one another.

Each of the plurality of data lines DL may be configured to extend in a first direction.

Each of the plurality of gate lines GL may be configured to extend in a second direction.

For example, the first direction may be the column or vertical direction, and the second direction may be the row or horizontal direction.

In another example, the first direction may be the row or horizontal direction, and the second direction may be the column or vertical direction.

The data driving circuit 220 may be a circuit for driving the plurality of data lines DL, and can supply data signals to the plurality of data lines DL.

The gate driving circuit 230 may be a circuit for driving a plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data Data based on the input image data to the data driving circuit 220.

The data driving circuit 220 can supply data signals to the plurality of data lines DL according to driving timing control of the display controller 240.

The data driving circuit 220 can receive digital image data Data from the display controller 240, convert the received image data Data into analog data signals, and output the resulting analog data signals to the plurality of data lines DL.

The gate driving circuit 230 can supply gate signals to the plurality of gate lines GL according to timing control of the display controller 240.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more embodiments, the data driving circuit 220 may be connected to the display panel 210 by a tape-automated-bonding (TAB) technique, or connected to a conductive pad such as a bonding pad of the display panel 210 by a chip-on-glass (COG) technique or a chip-on-panel (COP) technique, or connected to the display panel 210 by a chip-on-film (COF) technique.

In one or more embodiments, the gate driving circuit 230 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique.

In one or more embodiments, the gate driving circuit 230 may be disposed in the non-display area NDA of the display panel 110 by a gate-in-panel (GIP) technique.

The gate driving circuit 230 may be disposed on the substrate, or connected to the substrate.

In an example where the gate driving circuit 230 is implemented by the GIP technique, the gate driving circuit 230 may be disposed in the non-display area NDA of the substrate SUB.

The gate driving circuit 230 may be connected to the substrate SUB in an example where the gate driving circuit 230 is implemented by the chip-on-glass (COG) technique, the chip-on-film (COF) technique, or the like.

In one or more embodiments, at least one of the data driving circuit 220 and the gate driving circuit 230 may be disposed in the display area DA of the display panel 110.

For example, at least one of the data driving circuit 220 and the gate driving circuit 230 may be configured not to overlap with subpixels SP, or configured to overlap with one or more, or all, of the subpixels SP, or at least respective one or more portions of one or more subpixels.

The data driving circuit 220 may be disposed in, and/or electrically connected to, but not limited to, one side or portion (e.g., an upper edge or a lower edge) of the display panel 110.

In one or more embodiments, the data driving circuit 220 may be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The gate driving circuit 230 may be located in, and/or electrically connected to, but not limited to, one side or portion (e.g., a left edge or a right edge) of the display panel 110.

In one or more embodiments, the gate driving circuit 230 may be located in, and/or electrically connected to, but not limited to, two sides or portions (e.g., a left edge and a right edge) of the panel 110 or at least two of four sides or portions (e.g., an upper edge, a lower edge, the left edge, and the right edge) of the panel 110 according to driving schemes, panel design schemes, or the like.

The display controller 240 may be implemented in a separate component from the data driving circuit 220, or incorporated in the data driving circuit 220 and thus implemented in an integrated circuit.

The display controller 240 may be a timing controller used in the typical display technology or a controller or a control device capable of performing other control functions in addition to the function of the typical timing controller. In one or more embodiments, the display controller 140 may be a controller or a control device different from the timing controller, or a circuitry or a component included in the controller or the control device.

The display controller 240 may be implemented with various circuits or electronic components such as an integrated circuit (IC), a field programmable gate array (FPGA), an application specific integrated circuit (ASIC), a processor, and/or the like.

The display controller 240 may be mounted on a printed circuit board, a flexible printed circuit, and/or the like and be electrically connected to the gate driving circuit 230 and the data driving circuit 220 through the printed circuit board, flexible printed circuit, and/or the like.

The display controller 240 can transmit signals to, and receive signals from, the data driving circuit 220 via one or more predefined interfaces.

For example, such interfaces may include a low voltage differential signaling (LVDS) interface, an embedded clock point-point interface (EPI), a serial peripheral interface (SPI), and the like.

In one or more embodiments, in order to further provide a touch sensing function, as well as an image display function, the display device 100 may include at least one touch sensor, and a touch sensing circuit capable of detecting the occurrence of a touch event by a touch object such as a finger, a pen, or the like, or detecting a corresponding touch location (or touch coordinates), by sensing the touch sensor.

The touch sensing circuit may include a touch driving circuit 260 capable of generating and providing touch sensing data by driving and sensing the touch sensor, a touch controller 270 capable of detecting the occurrence of a touch event or detecting a touch location (or touch coordinates) using the touch sensing data, and one or more other components.

The touch sensor may include a plurality of touch electrodes.

The touch sensor may further include a plurality of touch lines for electrically connecting the plurality of touch electrodes to the touch driving circuit 260.

The touch sensor may be implemented in the form of a touch panel located outside of the display panel 110 or be integrated inside of the display panel 110.

In the example where the touch sensor is implemented in the form of the touch panel located outside of the display panel 110, such a touch sensor may be referred to as an add-on type.

In the example where the add-on type of touch sensor is disposed in the display device 100, the touch panel and the display panel 110 may be separately manufactured and combined in an assembly process.

The add-on type of touch panel may include a touch panel substrate and a plurality of touch electrodes disposed on the touch panel substrate.

In the example where the touch sensor is integrated inside of the display panel 110, the touch sensor may be formed on the substrate SUB together with signal lines and electrodes related to display driving during the process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrode and an object such as a finger, a pen, and/or the like.

According to the self-capacitance sensing technique, each of a plurality of touch electrodes can serve as both a driving touch electrode and a sensing touch electrode.

The touch driving circuit 260 can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes.

According to the mutual-capacitance sensing technique, a plurality of touch electrodes may be divided into driving touch electrodes and sensing touch electrodes.

The touch driving circuit 260 can drive the driving touch electrodes and sense the sensing touch electrodes.

The touch driving circuit 260 and the touch controller 270 included in the touch sensing circuit may be implemented in separate devices or in a single device.

Further, the touch driving circuit 260 and the data driving circuit 220 may be implemented in separate devices or in a single device.

The display device 100 may further include a power supply circuit for supplying various types of power to the display driving circuit and/or the touch sensing circuit.

In some embodiments, the display device 100 may be a mobile terminal such as a smart phone, a tablet, or the like, or a monitor, a television (TV), or the like. Such devices may be configured in various types, sizes, and shapes. The display device 100 according to embodiments of the present disclosure are not limited thereto, and may include various types, sizes, and shapes configured to display information or images.

As described above, the display area DA of the display panel 110 may include the normal area NA and the one or more optical areas (OA1 and/or OA2) as illustrated in FIG. 1.

The normal area NA and the one or more optical areas (OA1 and/or OA2) may be areas configured to allow images to be displayed.

It should be noted here that the normal area NA may be an area in which a light transmissive structure need not be implemented, and the one or more optical areas (OA1 and/or OA2) may be areas in which a light transmissive structure need be implemented.

As discussed above, even though the display area DA of the display panel 110 may include the one or more optical areas (OA1 and/or OA2) together with the normal area NA, for convenience of description, discussions that follow are provided based on examples where the display area DA includes both the first and second optical areas (OA1 and OA2).

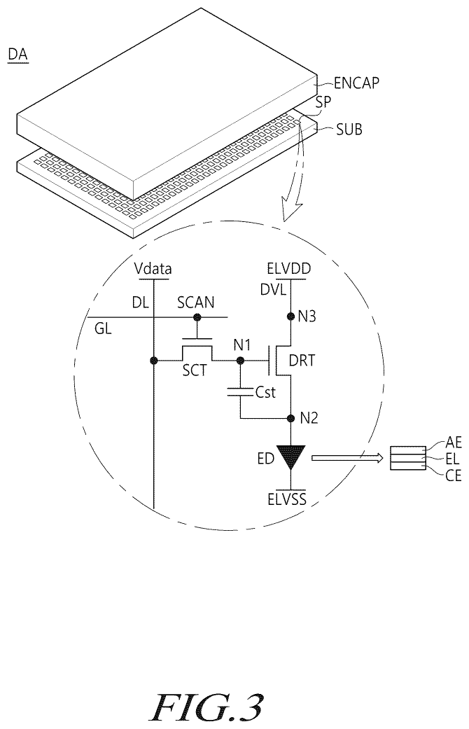

FIG. 3 illustrates an example equivalent circuit of a subpixel SP in the display panel 110 according to one or more embodiments of the present disclosure.

Each of subpixels SP disposed in the normal area NA, the first optical area OA1, and the second optical area OA2 included in the display area DA of the display panel 110 may include a light emitting element ED, a driving transistor DRT for driving the light emitting element ED, a scan transistor SCT for passing a data voltage Vdata to a first node N1 of the driving transistor DRT, a storage capacitor Cst for maintaining a voltage at an approximate constant level during one frame, and the like.

The driving transistor DRT may include the first node N1 to which a data voltage is applied, a second node N2 electrically connected to the light emitting element ED, and a third node N3 to which a driving voltage ELVDD delivered through a driving voltage line DVL is applied.

In the driving transistor DRT, the first node N1 may be a gate node, the second node N2 may be a source node or a drain node, and the third node N3 may be the drain node or the source node.

The light emitting element ED may include a first electrode layer AE, an emission layer EL, and a second electrode layer CE.

The first electrode layer AE may be a pixel electrode disposed in each subpixel SP, and may be electrically connected to the second node N2 of the driving transistor DRT of each subpixel SP.

The second electrode layer CE may be a common electrode commonly disposed in all or some of a plurality of subpixels SP. For example, a base voltage ELVSS may be applied to the second electrode layer CE.

For example, the first electrode layer AE may be a pixel electrode, and the second electrode layer CE may be a common electrode.

In another example, the first electrode layer AE may be the common electrode, and the second electrode layer CE may be the pixel electrode.

Hereinafter, for convenience of explanation, discussions are provided based on examples where the first electrode layer AE is a pixel electrode and the second electrode layer CE is a common electrode.

In one or more embodiments, the light emitting element ED may be an organic light emitting diode (OLED), an inorganic light emitting diode, or a quantum dot (QD) light emitting element.

In an example where the light emitting element ED is an organic light emitting diode, an emission layer EL of the light emitting element ED may include an organic emission layer containing an organic material.

The scan transistor SCT can be turned on and off by a scan signal SCAN, which is a gate signal applied through a gate line GL, and be electrically connected between the first node N1 of the driving transistor DRT and a data line DL.

The storage capacitor Cst may be electrically connected between the first node N1 and the second node N2 of the driving transistor DRT.

Each subpixel SP may include two transistors (2T: DRT and SCT) and one capacitor (1C: Cst) (which may be referred to as a “2T1C structure”) as illustrated in FIG. 3, and in some cases, may further include one or more transistors, or further include one or more capacitors.

The storage capacitor Cst may be an external capacitor intentionally designed to be located outside of the driving transistor DRT, other than an internal capacitor, such as a parasitic capacitor (e.g., a Cgs or a Cgd), that may be formed between the first node N1 and the second node N2 of the driving transistor DRT.

In one or more embodiments, each of the driving transistor DRT and the scan transistor SCT may be an n-type transistor, or a p-type transistor.

In one or more embodiments, each of the driving transistor DRT and the scan transistor SCT may be a low-temperature polycrystalline silicon transistor.

However, embodiments of the present disclosure are not limited thereto. For example, at least one of the driving transistor DRT and the scan transistor SCT may be an oxide thin film transistor.

Since circuit elements (in particular, a light emitting element ED implemented with an organic light emitting diode including an organic material) included in each subpixel SP are vulnerable to external moisture or oxygen, an encapsulation layer ENCAP may be configured to cover the circuit elements (e.g., the light emitting element ED) in order to prevent external moisture or oxygen from penetrating into such circuit elements.

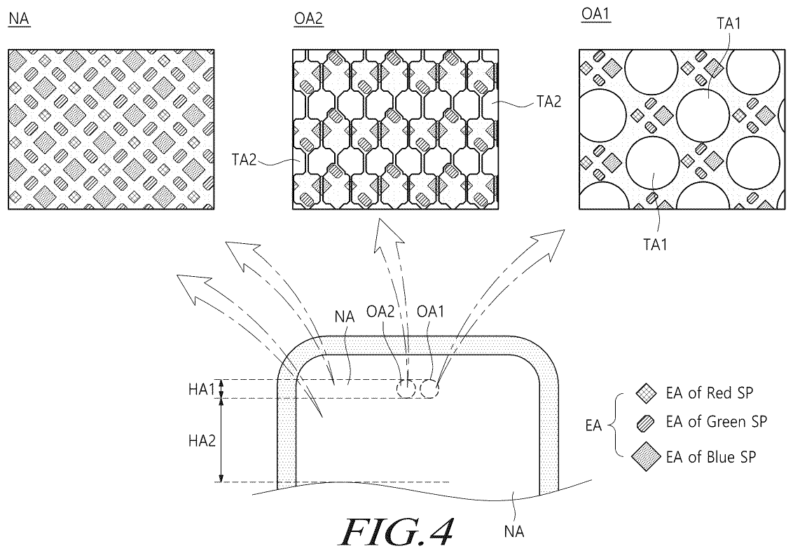

FIG. 4 illustrates arrangements of subpixels SP in example three areas (NA, OA1, and OA2) included in the display area of the display device 100 according to one or more embodiments of the present disclosure.

Referring to FIG. 4, in one or more embodiments, a plurality of subpixels SP may be disposed in each of the normal area NA, the first optical area OA1, and the second optical area OA2 included in the display area DA.

The plurality of subpixels SP may include, for example, a red subpixel (Red SP) emitting red light, a green subpixel (Green SP) emitting green light, and a blue subpixel (Blue SP) emitting blue light.

Accordingly, each of the normal area NA, the first optical area OA1, and the second optical area OA2 may include one or more light emitting areas EA of one or more red subpixels (Red SP), and one or more light emitting areas EA of one or more green subpixels (Green SP), and one or more light emitting areas EA of one or more blue subpixels (Blue SP).

Referring to FIG. 4, the normal area NA may not include a light transmissive structure, but may include light emitting areas EA.

In one or more embodiments, each of the first optical area OA1 and the second optical area OA2 may be needed to include a light transmissive structure, as well as light emitting areas EA.

Accordingly, in one or more embodiments, the first optical area OA1 may include one or more light emitting areas EA and one or more first transmissive areas TA1, and the second optical area OA2 may include one or more light emitting areas EA and one or more second transmissive areas TA2.

Light emitting areas EA and transmissive areas (TA1 and/or TA2) may be distinct from each other by whether light is allowed to be transmitted or not.

For example, light emitting areas EA may be areas not allowing light to be transmitted (e.g., not allowing light to be transmitted to the back of the display panel), and transmissive areas (TA1 and/or TA2) may be areas allowing light to be transmitted (e.g., allowing light to be transmitted to the back of the display panel).

Light emitting areas EA and transmissive areas (TA1 and/or TA2) may be also distinct from each other by whether a second electrode layer (e.g., the second electrode CE of FIG. 3) is disposed or not.

For example, while the second electrode CE may be disposed in the light emitting areas EA, the second electrode CE may not be disposed in the transmissive areas (TA1 and/or TA2).

In one or more embodiments, a light shield layer may be disposed in light emitting areas EA, and a light shield layer may not be disposed in transmissive areas (TA1 and/or TA2).

Since the first optical area OA1 includes first transmissive areas TA1 and the second optical area OA2 includes second transmissive areas TA2, both the first optical area OA1 and the second optical area OA2 may be areas configured to allow light to be transmitted.

A transmittance (a degree of transmission) of the first optical area OA1 and a transmittance (a degree of transmission) of the second optical area OA2 may be substantially the same.

Herein, substantially the same may mean a degree of being considered as being equivalent to each other taking into account minute differences due to errors in the process of manufacturing the display panel 110 or display device 100.

According to this definition, first transmissive areas TA1 of the first optical area OA1 and second transmissive areas TA2 of the second optical area OA2 may have substantially the same shape or size.

In one or more embodiments, even when first transmissive areas TA1 of the first optical area OA1 and second transmissive areas TA2 of the second optical area OA2 have different shapes or sizes, a ratio of the first transmissive areas TA1 to the first optical area OA1 and a ratio of the second transmissive areas TA2 to the second optical area OA2 may be substantially the same.

However, embodiments of the present disclosure are not limited thereto. For example, a transmittance (a degree of transmission) of the first optical area OA1 and a transmittance (a degree of transmission) of the second optical area OA2 may be different from each other.

In this implementation, first transmissive areas TA1 of the first optical area OA1 and second transmissive areas TA2 of the second optical area OA2 may have different shapes or sizes.

In one or more embodiments, even when first transmissive areas TA1 of the first optical area OA1 and second transmissive areas TA2 of the second optical area OA2 have substantially the same shape or size, a ratio of the first transmissive areas TA1 to the first optical area OA1 and a ratio of the second transmissive areas TA2 to the second optical area OA2 may be different from each other.

For example, in an example where the first optical electronic device 11 overlapping with the first optical area OA1 is a camera, and the second optical electronic device 12 overlapping with the second optical area OA2 is a sensor for detecting images, the camera may need a greater amount of light than the sensor.

In this example, a transmittance (a degree of transmission) of the first optical area OA1 may be greater than a transmittance (a degree of transmission) of the second optical area OA2.

In this implementation, all or each of first transmissive areas TA1 of the first optical area OA1 may have an area greater than all or each of second transmissive areas TA2 of the second optical area OA2.

In one or more embodiments, even when first transmissive areas TA1 of the first optical area OA1 and second transmissive areas TA2 of the second optical area OA2 have substantially the same size, a ratio of the first transmissive areas TA1 to the first optical area OA1 may be greater than a ratio of the second transmissive areas TA2 to the second optical area OA2.

In one or more embodiments, as shown in FIG. 4, first transmissive areas TA1 of the first optical area OA1 may have circular shapes in a cross-sectional view, but embodiments of the present disclosure for shapes of the first transmissive areas TA1 are not limited thereto.

For example, the first transmissive areas TA1 of the first optical area OA1 may have octagonal shapes in a plan view, or may have elliptical or polygonal shapes.

As discussed above, by changing the shape of the first transmissive areas TA1, the transmittance of the first transmissive areas TA1 can be adjusted and the area or size of light emitting areas of the first optical area OA1 can be adjusted.

Hereinafter, for convenience of explanation, discussions are provided based on examples where the transmittance (the degree of transmission) of the first optical area OA1 is greater than that of the second optical area OA2.

Further, as shown in FIG. 4, transmissive areas (TA1 and TA2) may be referred to as transparent areas, and transmittance may also be referred to as transparency.

In discussions that follow, as shown in FIG. 4, it is assumed that the first optical area OA1 and the second optical area OA2 are located at an upper portion of the display area DA of the display panel 110, and are disposed side by side left and right.

Referring to FIG. 4, a horizontal display area where the first optical area OA1 and the second optical area OA2 are disposed may be referred to as a first horizontal display area HA1, and a horizontal display area where the first optical area OA1 and the second optical area OA2 are not disposed may be referred to as a second horizontal display area HA2.

Referring to FIG. 4, the first horizontal display area HA1 may include the normal area NA, the first optical area OA1, and the second optical area OA2.

The second horizontal display area HA2 may include only the normal area NA.

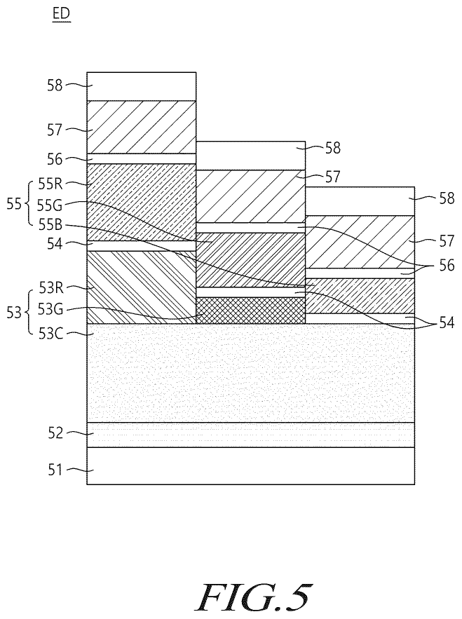

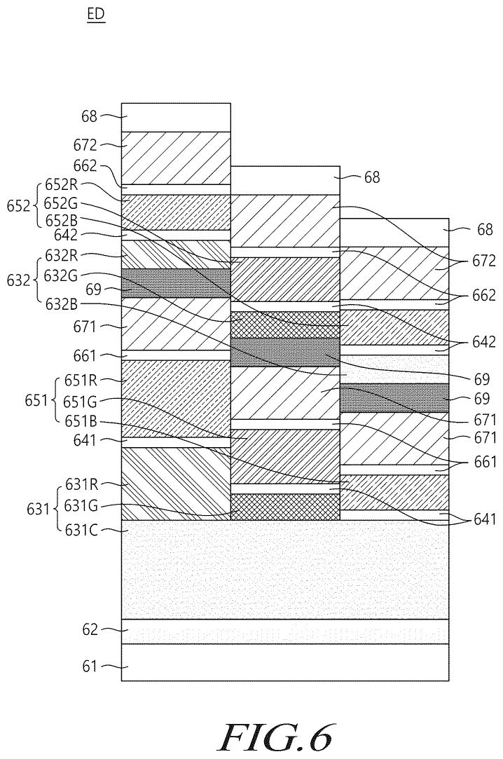

FIGS. 5 and 6 are cross-sectional views of example light emitting elements ED included in the display device 100 according to one or more embodiments of the present disclosure.

Referring to FIG. 5, in one or more embodiments, a stack of light emitting elements ED included in the display device 100 may include respective portions of a red subpixel R, a green subpixel G, and a blue subpixel B, which are disposed on the substrate 10 and configured to emit different colors.

The stack of the light emitting elements ED may include a first electrode layer 51 disposed on a substrate 10, a second electrode layer 58 disposed opposite to the first electrode layer 51, and an emission layer 55 disposed between the first electrode layer 51 and the second electrode layer 58.

The first electrode layer 51 may be an anode, and the second electrode layer 58 may be a cathode, but embodiments of the present disclosure are not limited thereto.

For example, in the case of an inverted type, the first electrode layer 51 may be a cathode and the second electrode layer 58 may be an anode.

It should be noted hereafter that discussions are provided based on examples where first and second electrode layers (51 and 58) of each light emitting device ED are an anode and a cathode, respectively.

At least one transistor (not shown in FIG. 5) disposed over the substrate 10 may include a source, drain, gate, and active layer, and the first electrode layer 51 may be electrically connected to any one of the source and the drain of the transistor through a contact hole formed in an insulating layer disposed on the substrate 10.

The first electrode layer 51 may include a material with a relatively high work function.

The first electrode layer 51 may include, for example, a transparent conductive oxide, such as indium tin oxide (ITO), indium zinc oxide (IZO), zinc oxide (ZnO), aluminum zinc oxide (AZO), indium oxide (In₂O₃), tin oxide (SnO₂), or the like, but embodiments of the present disclosure are not limited thereto.

The second electrode layer 58 may include a material with a relatively low work function, and for example, include a metal, an alloy, an electroconductive compound, or a mixture of two or more thereof.

For example, a transmissive electrode as the second electrode layer 58 may be obtained by forming, in the form of a thin film, lithium (Li), magnesium (Mg), aluminum (Al), aluminum-lithium (Al—Li), calcium (Ca), magnesium-indium (Mg—In), magnesium-silver (Mg—Ag), or the like.

In this regard, in one or more embodiments, various modifications may be made, such as forming a transmissive electrode using ITO or IZO to obtain a top emission light emitting element.

A capping layer (not shown in FIG. 5) may be disposed on the second electrode layer 58 to improve optical capability and maximize or at least increase emission efficiency.

For example, the capping layer may include a metal oxide layer, a metal nitride layer, or a metal nitrogen oxide layer.

For example, the capping layer may include MoOx (x=2˜4), Al₂O₃, Sb₂O₃, BaO, CdO, CaO, Ce₂O₃, CoO, Cu₂O, DyO, GdO, HfO₂, La₂O₃, Li₂O, MgO, NbO, NiO, Nd₂O₃, PdO, Sm₂O₃, ScO, SiO₂, SrO, Ta₂O₃, TiO, WO₃, VO₂, YbO, Y₂O₃, ZnO, ZrO, AlN, BN, NbN, SiN, TaN, TiN, VN, YbN, ZrN, SiON, AlON, or mixtures thereof, but embodiments of the present disclosure are not limited thereto.

Referring to FIG. 5, the emission layer 55 of the stack of the light emitting elements ED may include a red emission layer 55R of the red subpixel R, a green emission layer 55G of the green subpixel G, and a blue emission layer 55B of the blue subpixel B.

For example, wavelengths of light emitted from the red emission layer 55R, the green emission layer 55G, and the blue emission layer 55B become short in an order from the red emission layer 55R to the blue emission layer 55B.

The red emission layer 55R may include a red host and a red dopant.

The red host may use Alq₃, CBP, PVK, AND, TCTA, TPBI, TBADN, E3, DSA, or a mixture of two or more thereof, but embodiments of the present disclosure are not limited thereto.

The red dopant may use PtOEP, Ir(piq)₃, Btp₂Ir(acac), Ir(2-phq)₂(acac), Ir(2-phq)₃, Ir(flq)₂(acac), Ir(fliq)₂(acac), or compounds containing DCM or DCJTB, but embodiments of the present disclosure are not limited thereto.

The green emission layer 55G may include a green host and a green dopant.

The green host may use Alq₃, CBP, PVK, AND, TCTA, TPBI, TBADN, E3, DSA, or a mixture of two or more thereof, but embodiments of the present disclosure are not limited thereto.

The green dopant may use Ir(ppy)₃ tris(2-phenylpyridine) iridium, Ir(ppy)₂ (acac)(Bis(2-phenylpyridine)(Acetylacetonato)iridium(III), Ir(mppy)₃ (tris(2-(4-tolyl)phenylpiridine)iridium, C545T 10-(2benzothiazolyl)-1,1,7,7-tetramethyl-2,3,6,7-tetrahydro-1H,5H,11H-[1]benzopyrano [6,7,8-ij]-quinolizin11-one, or the like, but embodiments of the present disclosure are not limited thereto.

The blue emission layer 55B may include a blue host and a blue dopant.

The blue host may use Alq₃, CBP(4,4′-N, N′-dicabazole-biphenyl), PVK(poly(n-vinylcabazole), ADN(9,10-di(naphthalene-2-yl)anthracene), TCTA, TPBI(1,3,5-tris(N-phenylbenzimidazole-2-yl)benzene), TBADN(3-tert-butyl-9,10-di(naphth-2-yl) anthracene), E3, DSA(distyrylarylene), or a mixture of two or more thereof, but embodiments of the present disclosure are not limited thereto.

The blue dopant may use compounds containing F₂Irpic, (F₂ppy)₂Ir(tmd), Ir(dfppz)₃, ter-fluorene, DPAVBi(4,4′-bis(4diphenylaminostyryl)biphenyl, TBPe, and/or the like, but embodiments of the present disclosure are not limited thereto.

Referring to FIG. 5, the stack of the light emitting elements ED may include a hole transport layer 53 disposed between the first electrode layer 51 and the emission layer 55.

The hole transport layer 53 may include a common hole transport layer 53C disposed on a hole injection layer 52.

The hole transport layer 53 may include an emission auxiliary layer disposed between the hole transport layer 53 and the common hole transport layer 53C.

The emission auxiliary layer may include a red emission auxiliary layer 53R, a green emission auxiliary layer 53G, and a blue emission auxiliary layer (not shown) disposed on the hole transport layer 53C.

For example, the emission auxiliary layer may serve to transport holes and may include a hole transport material. The emission auxiliary layers may include the same material or compound, or may include different materials or compounds.

For example, the hole transport layer 53, the common hole transport layer 53C, the red emission auxiliary layer 53R, the green emission auxiliary layer 53G, and the blue emission auxiliary layer (not shown) may include materials containing tertiary amines or tertiary amines containing fluorene, but embodiments of the present disclosure are not limited thereto.

Referring to FIG. 5, the stack of the light emitting elements ED may include the hole injection layer 52 disposed on the first electrode layer 51, the hole transport layer 53 disposed on the hole injection layer 52, the emission layer 55 disposed on the hole transport layer 53, and an electron transport layer 57 disposed on the emission layer 55, but embodiments of the present disclosure are not limited thereto.

When a voltage is applied between the first electrode layer 51 and the second electrode layer 58 of the stack of the light emitting elements ED, holes passing through the hole transport layer 53 and electrons passing through the electron transport layer 57 can move to the emission layer 55 and form excitons, this enabling the emission layer 55 to emit visible light.

Referring to FIG. 5, the stack of the light emitting elements ED may include an electron blocking layer 54 between the hole transport layer 53 and the emission layer 55.

However, embodiments of the present disclosure are not limited thereto. For example, the stack of the light emitting elements ED may not include the electron blocking layer 54.

The electron blocking layer 54 may include at least one of Tris(phenylpyrazole)iridium, BPAPF (9,9-bis[4-(N,N-bis-biphenyl-4-ylamino)phenyl]-9H-fluorene), Bis[4-(p,p-ditolylamino)phenyl]diphenylsilane, NPD (4,4′-bis[N-(1-napthyl)-N-phenyl-amino]biphenyl), mCP(N,N′-dicarbazolyl-3,5-benzene), and MPMP (bis[4-(N,N-diethylamino)-2-methylphenyl](4-methylphenyl)methane), or a combination thereof, but embodiments of the present disclosure are not limited thereto.

In one or more embodiments, the electron blocking layer 54 may include an inorganic compound. For example, the electron blocking layer 144 may include at least one of a halide compound such as LiF, NaF, KF, RbF, CsF, FrF, MgF₂, CaF₂, SrF₂, BaF₂, LiCl, NaCl, KCl, RbCl, CsCl, FrCl, or the like, and an oxide such as Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CO, NaWO₄, KAlO₂, K₂SiO₃, B₂O₅, Al₂O₃, SiO₂, or the like, or include a combination of the halide compound and the oxide. However, embodiments of the present disclosure are not limited thereto.

The electron blocking layer 54 can serve as a buffer layer for blocking direct contact between the hole transport layer 53 and the emission layer 55, and serve to prevent electrons from easily flowing into the hole transport layer 53.

For example, the electron blocking layer 54 can improve the efficiency and lifetime of the light emitting elements ED by controlling injection and movement of electrons, and combination of electrons and holes.

The electron transport layer 57 may be disposed on the emission layer 55.

The electron transport layer 57 can control a movement speed of electrons so that electrons and holes can meet in the emission layer 55 and enable the emission layer 55 to emit light.

The electron transport layer 57 may include a material allowing electrons to move at a speed several times higher than a speed at which other materials allows electrons to move.

The electron transport layer 57 may include, for example, at least one of Alq₃ (tris(8-hydroxyquinolino)aluminum), PBD, TAZ, spiro-PBD, BAlq, and SAlq, or a combination thereof, but embodiments of the present disclosure are not limited thereto.

An electron injection layer (not shown) may be disposed on the electron transport layer 57.

The electron injection layer (not shown) can transfer electrons flowing from the second electrode layer 58 to the electron transport layer 57.

Referring to FIG. 5, the stack of the light emitting elements ED may include a hole blocking layer 56 between the emission layer 55 and the electron transport layer 57.

However, embodiments of the present disclosure are not limited thereto. For example, the stack of the light emitting elements ED may not include the hole blocking layer 56.

The hole blocking layer 56 can serve as a buffer layer for blocking direct contact between the electron transport layer 57 and the emission layer 55, and serve to prevent holes from easily flowing into the electron transport layer 57.

For example, the hole blocking layer 56 can improve the efficiency and lifetime of the light emitting elements ED by controlling injection and movement of holes, and combination of holes and electrons.

As described above, an example where each light emitting element has a single stack structure has been described with reference to FIG. 5.

Hereinafter, another example where each light emitting element ED has a multi-stack structure is described with reference to FIG. 6.

Referring to FIG. 6, in one or more embodiments, each light emitting element ED has a multi-stack structure including a first stack emission layer 651 and a second stack emission layer 652. Each light emitting element ED may also include a first electrode layer 61 disposed on a substrate 10, a hole injection layer 62 on the first electrode layer 61, and a second electrode layer 68 disposed opposite to the first electrode layer 61.

For example, the first stack emission layer 651 and the second stack emission layer 652 may include an emission material capable of emitting light with the same color.

Referring to FIG. 6, each light emitting element ED may be configured with a first stack structure including the first stack emission layer 651, and a second stack structure including the second stack emission layer 652.

A first hole transport layer 631 (including 631C, 631G and 631R), a first electron blocking layer 641, the first stack emission layer 651 (including 651R, 651G and 651B), a first hole blocking layer 661, and a first electron transport layer 671 included in the first stack structure may be the same, or substantially the same, as the hole transport layer 53, the electron blocking layer 54, the emission layer 55, the hole blocking layer 56, and electron transport layer 57 of FIG. 5, respectively. Thus, for simplicity, discussions on these elements are omitted.

In one or more embodiments, in the second stack structure, a charge generation layer 69, a second hole transport layer 632 (including 632R, 632G and 632B), a second electron blocking layer 642, the second stack emission layer 652 (including 652R, 652G and 652B), a second hole blocking layer 662, and a second electron transport layer 672 may be disposed between a second electrode layer 68 and the first electron transport layer 671.

In one or more embodiments, the charge generation layer 69 may be located on the first electron transport layer 671, the second hole transport layer 632 may be located on the charge generation layer 69, the second electron blocking layer 642 may be located on the second hole transport layer 632, the second stack emission layer 652 may be located on the second electron blocking layer 642, the second hole blocking layer 662 may be located on the second stack emission layer 652, and the second electron transport layer 672 may be disposed on the second hole blocking layer 662.

The second electron transport layer 672 may be disposed adjacent to the second stack emission layer 652 and can transfer electrons to the second stack emission layer 652.

The charge generation layer 69 may be disposed between the first electron transport layer 671 and the second hole transport layer 632 and can transfer electrons to the first electron transport layer 671.

The first hole transport layer 671 may be disposed adjacent to the first stack emission layer 651 and can transfer holes to the first stack emission layer 651.

Although FIG. 6 illustrates each light emitting element includes two-stack structure, embodiments of the present disclosure are not limited thereto. For example, each light emitting element may have other multi-stack structures such as a three-stack structure, a four-stack structure, and the like.

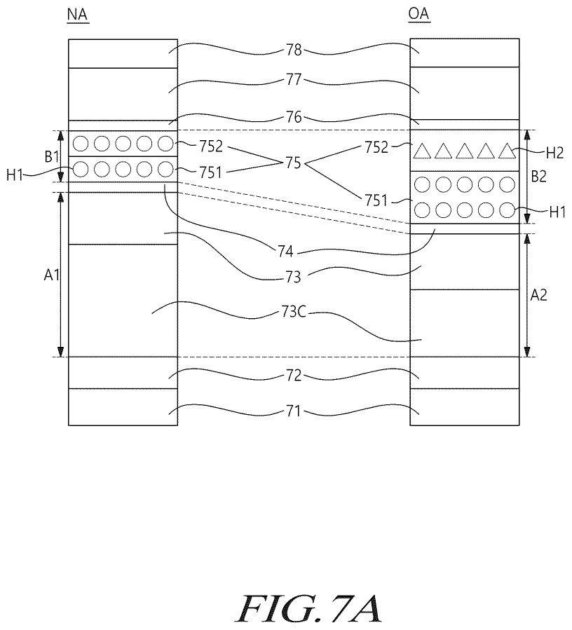

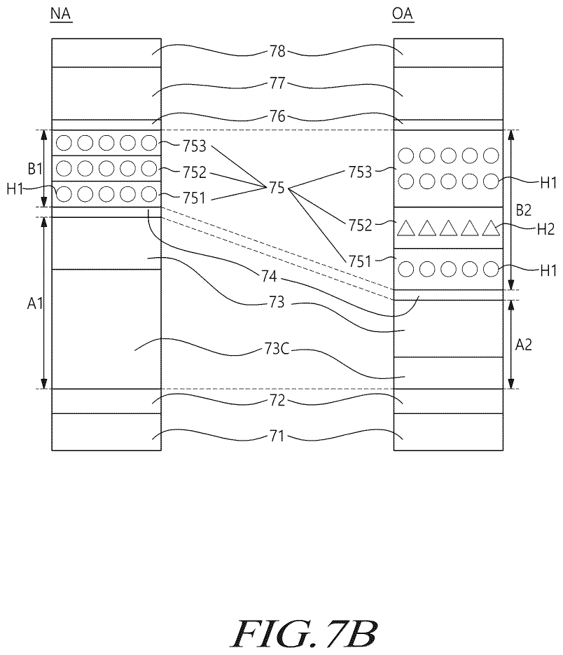

FIGS. 7A and 7B are cross-sectional views of example light emitting elements ED disposed in a normal area NA and an optical area OA of the display device 100 according to one or more embodiments of the present disclosure.

Although FIGS. 7A and 7B illustrate example light emitting elements configured with the single stack structure for convenience of explanation, however, embodiments of the present disclosure are not limited thereto. The configurations of FIGS. 7A and 7B and related discussions can be equally applied to a multi-stack structure.

It should be noted that for convenience of explanation, in FIGS. 7A and 7B, parts of a material included in emission layers 75 are shown in the form of particles. For example, a first host H1 and a second host H2, which are parts of a material included in emission layers 75, may be shown in the form of particles.

Referring to FIG. 7A, a first electrode layer 71, a hole injection layer 72, a common hole transport layer 73C, a hole transport layer 73, an electron blocking layer 74, an emission layer 75, a hole blocking layer 76, an electron transport layer 77, and a second electrode layer 78, which are included in the normal area NA and the optical area OA, may be the same, or substantially the same, as the first electrode layer 51, the hole injection layer 52, the common hole transport layer 53C, the hole transport layer 53, the electron blocking layer 54, the emission layer 55, the hole blocking layer 56, the electron transport layer 57, and the second electrode layer 58 in FIG. 5 described above. Thus, for simplicity, discussions on these elements are omitted.

Referring to FIG. 7A, each of respective emission layers 75 of the normal area NA and the optical area OA may include a first emission layer 751 and a second emission layer 752.

The first emission layer 751 may be located on the electron blocking layer 74, and the second emission layer 752 may be located on the first emission layer 751.

In one or more embodiments, the first emission layer 751 and the second emission layer 752 of the normal area NA may include a first host H1.

Although FIG. 7A illustrates that the first emission layer 751 and the second emission layer 752 of the normal area NA are located in different layers, however, embodiments of the present disclosure are not limited thereto. In the example where the first emission layer 751 and the second emission layer 752 of the normal area NA include the same material by including the first host H1, the first emission layer 751 and the second emission layer 752 may be regarded as a single layer.

In one or more embodiments, the first emission layer 751 and the second emission layer 752 of the optical area OA may include the first host H1 and a second host H2, respectively.

For example, the second host H2 may be different from the first host H1.

It should be noted that the numbers of particles of the first hosts H1 and the second hosts H2 shown in the normal area NA and the optical area OA of FIG. 7A are merely for convenience of explanation, and therefore, embodiments of the present disclosure are not limited thereto. Respective amounts of particles of the first hosts H1 and the second hosts H2 may vary due to errors in the manufacturing process.

In one or more embodiments, the first emission layer 751 and the second emission layer 752 of the normal area NA may include a same type of dopant.

In one or more embodiments, the first emission layer 751 and the second emission layer 752 of the optical area OA may include a first dopant (not shown) and a second dopant (not shown), respectively. In one or more embodiments, referring to FIG. 7A, the thickness of the first emission layer 751 in the optical area OA is larger than the thickness of the first emission layer 751 in the normal area NA, and the thickness of the second emission layer 752 in the optical area OA is larger than the thickness of the second emission layer 752 in the normal area NA. Thus, an area for emitting light is increase, and the efficient is also increased.

For example, the second dopant and the first dopant may be different from each other.

However, embodiments of the present disclosure are not limited thereto. For example, the first emission layer 751 and the second emission layer 752 of the optical area OA may include a same type of dopant.

The lifetime of the light emitting elements ED disposed in the optical area OA can be increased by adjusting the types and amounts of one or more hosts and one or more dopants included in the first emission layer 751 and the second emission layer 752 of the optical area OA, which may be different from the normal area NA.

Referring to FIG. 7A, as the number of emission layers 75 is increased (i.e., the first emission layer 751 and the second emission layer 752), the thickness (B1 and B2) of the entire emission layer 75 may increase.

For example, a thickness (A1 or A2) of the hole transport layer 73 or the common hole transport layer 73C may be adjusted to compensate for the increased thickness (B1 and B2) of the entire emission layer 75. The combination of the hole transport layer 73 and the common hole transport layer 73C may also be called the hole transport layer 73. Besides, the common hole transport layer 73C may be omitted.

Referring to FIG. 7A, as the thickness B2 of the emission layer 75 in the optical area OA increases compared to the thickness B1 of the emission layer 75 in the normal area NA, the increased emission layer thickness B2 in the optical area OA may be compensated for by reducing a thickness A2 of the hole transport layer 73 and the common hole transport layer 73C in the optical area OA rather than a thickness A1 of the hole transport layer 73 and the common hole transport layer 73C in the normal area NA.

For example, the sum of respective thicknesses of the hole transport layer 73, the common hole transport layer 73C, the first emission layer 751, and the second emission layer 752 in the normal area NA may be the same, or substantially the same, as the sum of respective thicknesses of the hole transport layer 73, the common hole transport layer 73C, the first emission layer 751, and the second emission layer 752 in the optical area OA.

In one or more embodiments, the first emission layer 751 and the second emission layer 752 of light emitting elements ED may include a phosphorescent host and a phosphorescent dopant, or a fluorescent host and a fluorescent dopant, depending on design requirements.

As described above, the example where the emission layer 75 has two layers has been described with reference to FIG. 7A.

Hereinafter, an example where an emission layer 75 has three layers is described with reference to FIG. 7B.

Referring to FIG. 7B, a first electrode layer 71, a hole injection layer 72, a common hole transport layer 73C, a hole transport layer 73, an electron blocking layer 74, an emission layer 75, a hole blocking layer 76, an electron transport layer 77, and a second electrode layer 78, which are included in the normal area NA and the optical area OA, may be the same, or substantially the same, as the first electrode layer 51, the hole injection layer 52, the common hole transport layer 53C, the hole transport layer 53, the electron blocking layer 54, the emission layer 55, the hole blocking layer 56, the electron transport layer 57, and the second electrode layer 58 in FIG. 5 described above. Thus, for simplicity, discussions on these elements are omitted.

Referring to FIG. 7B, each of respective emission layers 75 of the normal area NA and the optical area OA may include a first emission layer 751, a second emission layer 752, and a third emission layer 753.

The first emission layer 751 may be located on the electron blocking layer 74, the second emission layer 752 may be located on the first emission layer 751, and the third emission layer 753 may be located on the second emission layer 752.

In one or more embodiments, the first emission layer 751, the second emission layer 752, and the third emission layer 753 of the normal area NA may include a first host H1.

Although FIG. 7B illustrates that the first emission layer 751, the second emission layer 752, and the third emission layer 753 of the normal area NA are located in different layers, however, embodiments of the present disclosure are not limited thereto. In the example where the first emission layer 751, the second emission layer 752, and the third emission layer 753 of the normal area NA include the same material by including the first host H1, the first emission layer 751, the second emission layer 752, and the third emission layer 753 may be regarded as a single layer.

In one or more embodiments, the first emission layer 751 and the third emission layer 753 of the optical area OA may include the first host H1, and the second emission layer 752 of the optical area OA may include a second host H2.

For example, the second host H2 may be different from the first host H1.

It should be noted that the numbers of particles of the first hosts H1 and the second hosts H2 shown in the normal area NA and the optical area OA of FIG. 7B are merely for convenience of explanation, and therefore, embodiments of the present disclosure are not limited thereto. Respective amounts of particles of the first hosts H1 and the second hosts H2 may vary due to errors in the manufacturing process.

In one or more embodiments, the first emission layer 751, the second emission layer 752, and the third emission layer 753 of the normal area NA may include a same type of dopant.

In one or more embodiments, the first emission layer 751 and the third emission layer 753 of the optical area OA may include a first dopant, and the second emission layer 752 of the optical area OA may include a second dopant.

For example, the second dopant and the first dopant may be different from each other.

However, embodiments of the present disclosure are not limited thereto. For example, the first emission layer 751, the second emission layer 752, and the third emission layer 753 of the optical area OA may include a same type of dopant.

The lifetime of the light emitting elements ED disposed in the optical area OA can be increased by adjusting the types and amounts of one or more hosts and one or more dopants included in the first emission layer 751, the second emission layer 752, and the third emission layer 753 of the optical area OA, which may be different from the normal area NA.

Referring to FIG. 7B, as the number of emission layers 75 is increased (i.e., the first emission layer 751, the second emission layer 752, and the third emission layer 753), the thickness (B1 and B2) of the entire emission layer 75 may increase.

For example, a thickness (A1 or A2) of the hole transport layer 73 or the common hole transport layer 73C may be adjusted to compensate for the increased thickness (B1 and B2) of the entire emission layer 75.

Referring to FIG. 7B, as the thickness B2 of the emission layer 75 in the optical area OA increases compared to the thickness B1 of the emission layer 75 in the normal area NA, the increased emission layer thickness B2 in the optical area OA may be compensated for by reducing a thickness A2 of the hole transport layer 73 and the common hole transport layer 73C in the optical area OA rather than a thickness A1 of the hole transport layer 73 and the common hole transport layer 73C in the normal area NA.

For example, the sum of respective thicknesses of the hole transport layer 73, the common hole transport layer 73C, the first emission layer 751, the second emission layer 752, and the third emission layer 753 in the normal area NA may be the same as the sum of respective thicknesses of the hole transport layer 73, the common hole transport layer 73C, the first emission layer 751, the second emission layer 752, and the third emission layer 753 in the optical area OA.

In one or more embodiments, the first emission layer 751 and the second emission layer 752 of light emitting elements ED may include a phosphorescent host and a phosphorescent dopant, or a fluorescent host and a fluorescent dopant, depending on design requirements.

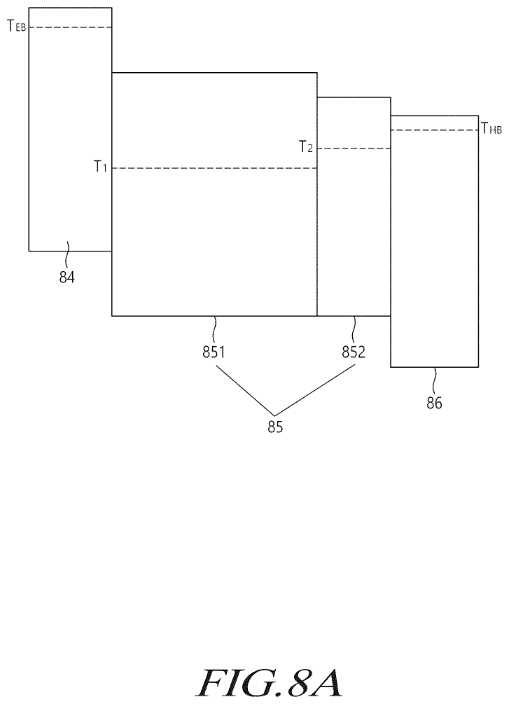

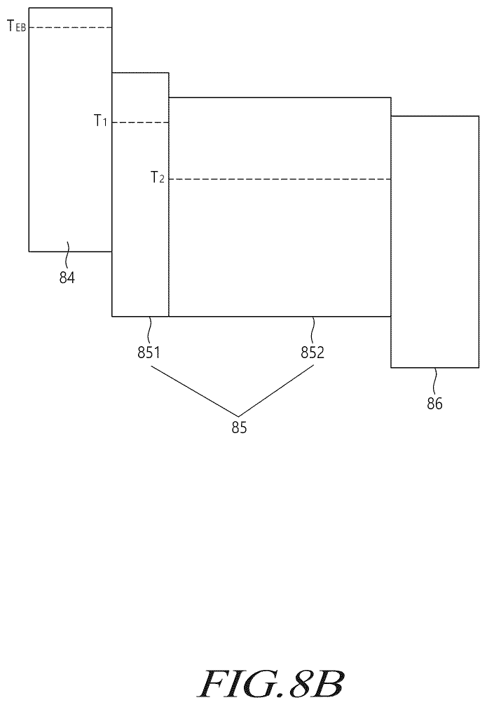

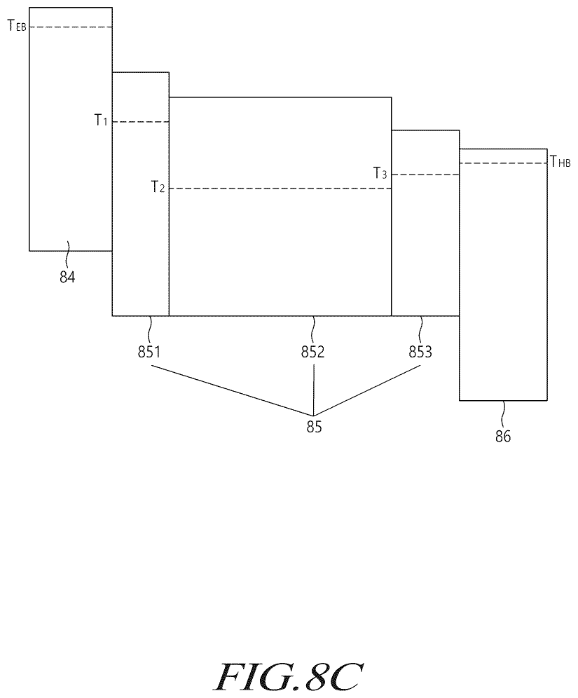

FIGS. 8A to 8C illustrate triple state energy levels of example light emitting elements ED included in the display device 100 according to one or more embodiments of the present disclosure.

In one or more embodiments, FIGS. 8A and 8B illustrate that an emission layer 85 of a light emitting element ED includes a first emission layer 851 and a second emission layer 852, and the emission layer 85 disposed between an electron blocking layer 84 and a hole blocking layer 86 has two layers.

In one or more embodiments, FIG. 8C illustrate that an emission layer 85 of a light emitting element ED includes a first emission layer 851, a second emission layer 852, and a third emission layer 853, and the emission layer 85 disposed between an electron blocking layer 84 and a hole blocking layer 86 has three layers.

Referring to FIG. 8A, the second emission layer 852 may be disposed between the hole blocking layer 86 and the first emission layer 851 to prevent triplet polaron quenching (TPQ).

For example, the thickness of the second emission layer 852 may preferably be 2 nm or more and 5 nm or less.

In this example, the first emission layer 851 may be a main emission layer, and the second emission layer 852 may be an auxiliary emission layer.

According to this example, the second emission layer 852 can transfer energy created by combining holes accumulated at the interface of the hole blocking layer 86 and electrons transferred through the hole blocking layer 86 to the first emission layer 851.

Here, for stably transferring electrons and blocking holes, Equation 1 can be satisfied in the optical area OA, or at least one of Equation 2 or Equation 3 can be satisfied.

$${T}_{1} < {T}_{2} < {T}_{HB} \qquad [ Equation 1 ]$$

In Equation 1, T_{HB} is a triplet state energy level of the hole blocking layer, T₁ is a triplet state energy level of the first emission layer, and T₂ is a triplet state energy level of the second emission layer.

$${L}_{HB} < {L}_{2} < {L}_{1} \qquad [ Equation 2 ]$$

In Equation 2, L_{HB} is a lowest unoccupied molecular orbital (LUMO) energy level of the hole blocking layer, L₁ is a LUMO energy level of the first emission layer, and L₂ is a LUMO energy level of the second emission layer.

$$\vert {H}_{2} - {H}_{1} \vert \leq 0.1 eV \qquad [ Equation 3 ]$$

In Equation 3, H₁ is a highest occupied molecular orbital (HOMO) energy level of the first emission layer, and H₂ is a HOMO energy level of the second emission layer.

When the light emitting element ED satisfies Equation 1, and satisfies at least one of Equation 2 or Equation 3, phosphorescence efficiency can be increased.

Referring to FIG. 8B, the second emission layer 852 may be disposed between the hole blocking layer 86 and the first emission layer 851 to prevent Triplet Triplet Annihilation (TTA).

For example, the thickness of the first emission layer 851 may preferably be 2 nm or more and 5 nm or less.

In this example, the second emission layer 852 may be a main emission layer, and the first emission layer 851 may be an auxiliary emission layer.

According to this example, the first emission layer 851 can transfer energy created by combining electrons accumulated at the interface of the electron blocking layer 84 and holes transferred through the electron blocking layer 84 to the second emission layer 852.

Here, for stably transferring holes and blocking electrons, Equation 4 can be satisfied in the optical area OA, or at least one of Equation 5 or Equation 6 can be satisfied.

$${T}_{2} < {T}_{1} < {T}_{EB} \qquad [ Equation 4 ]$$

In Equation 4, T_{EB} is a triplet state energy level of the electron blocking layer, T₁ is a triplet state energy level of the first emission layer, and T₂ is a triplet state energy level of the second emission layer.

$${L}_{2} < {L}_{1} < {L}_{EB} \qquad [ Equation 5 ]$$

In Equation 5, L_{EB} is a lowest unoccupied molecular orbital (LUMO) energy level of the electron blocking layer, L₁ is a LUMO energy level of the first emission layer, and L₂ is a LUMO energy level of the second emission layer.

$${H}_{2} < {H}_{1} < {H}_{EB} \qquad [ Equation 6 ]$$

In Equation 6, H_{EB} is a highest occupied molecular orbital (HOMO) energy level of the electron blocking layer, H₁ is a HOMO energy level of the first emission layer, and H₂ is a HOMO energy level of the second emission layer.

When the light emitting element ED satisfies Equation 4, and satisfies at least one of Equation 5 or Equation 6, fluorescence efficiency can be increased.

Referring to FIG. 8C, the third emission layer 853 may be disposed between the hole blocking layer 86 and the second emission layer 852 to prevent triplet polaron quenching (TPQ) in the emission layer 85 and the hole blocking layer 86.

For example, a thickness of the first emission layer 851 and the third emission layer 853 may preferably be 2 nm or more and 5 nm or less.

In this example, the second emission layer 852 may be a main emission layer, and the first emission layer 851 and the third emission layer 851 may be auxiliary emission layers.

According to this example, the first emission layer 851 may have lower electron transport capability but greater hole transport capability than the second emission layer 852 and the third emission layer 853.

Here, for stably transferring energy and emitting light, Equations 7 and 8 can be satisfied in the optical area OA.

$${T}_{1} > {T}_{2} \qquad [ Equation 7 ]$$

$${T}_{3} > {T}_{2} \qquad [ Equation 8 ]$$

In Equation 7 and Equation 8, T₁ is a triplet state energy level of the first emission layer, T₂ is a triplet state energy level of the second emission layer, and T₃ is a triplet state energy level of the third emission layer.

When the light emitting element ED satisfies Equation 7 and Equation 8, since the triplet energy level T2 of the second emission layer 852 is lower than the triplet energy level T1 of the first emission layer 851 and the triplet energy level T3 of the third emission layer 853, energy may be transferred from the auxiliary emission layers 851 and 853 to the main emission layer 852.

Here, for stably transferring energy and emitting light, at least one of Equation 9, Equation 10, Equation 11 and Equation 12 may be preferably satisfied.

$${T}_{EB} > {T}_{1} > {T}_{2} \qquad [ Equation 9 ]$$

In Equation 9, T₁ is a triplet state energy level of the first emission layer, T₂ is a triplet state energy level of the second emission layer, and T_{EB} is a triplet state energy level of the electron blocking layer.

$${T}_{HB} > {T}_{3} > {T}_{2} \qquad [ Equation 10 ]$$

In Equation 10, T₂ is a triplet state energy level of the second emission layer, T₃ is a triplet state energy level of the third emission layer, and T_{HB} is a triplet state energy level of the hole blocking layer.

$${L}_{1} > {L}_{2} \qquad [ Equation 11 ]$$

In Equation 11,

L₁ is a lowest unoccupied molecular orbital (LUMO) energy level of the first emission layer, and L₂ is a LUMO energy level of the second emission layer.

$${H}_{1} > {H}_{2} \qquad [ Equation 12 ]$$

In Equation 12,
H₁ is a highest occupied molecular orbital (HOMO) energy level of the first emission layer, and H₂ is a HOMO energy level of the second emission layer.

The values of HOMO, LUMO, and T described in FIGS. 8A to 8C may be values measured by cyclic voltammetry.

Manufacturing Light Emitting Elements According to Embodiments of the Present Disclosure, and Evaluation for these Light Emitting Elements

### Embodiment 1

A light emitting element has been manufactured as follows. A hole injection layer has been formed by depositing a 2-TNATA film using a vacuum deposition technique on an indium tin oxide (ITO) layer (serving as an anode) formed on a glass substrate, and thereafter, a hole transport layer has been formed by depositing NPD using the vacuum deposition technique on the hole injection layer.

Next, a first emission layer with a thickness of 5 nm including a first host material and a dopant material has been deposited on the hole transport layer, and thereafter, a second emission layer with a thickness of 17.5 nm including a second host material and a dopant material has been deposited on the first emission layer.

Next, a hole blocking layer has been formed by depositing BAlq using the vacuum deposition technique on the second emission layer, and an electron transport layer has been formed by depositing Alq₃ on the hole blocking layer.

Thereafter, an electron injection layer has been formed by depositing LiF on the electron transport layer, and then, a cathode has been formed by depositing Al on the electron injection layer.

### Embodiment 2

Alight emitting element of Embodiment 2 has been manufactured by the same process as Embodiment 1, except that a second emission layer with a thickness of 17.5 nm including a second host material and a dopant material has been deposited on a hole transport layer, and thereafter, a first emission layer with a thickness of 5 nm including a first host material and a dopant material has been deposited on the second emission layer.

### Comparative Example

Alight emitting element of Comparative example has been manufactured by the same process as Embodiment 1, except that an emission layer with a thickness of 22.5 nm including a second host material and a dopant material has been deposited on a hole transport layer.

To evaluate the light emitting elements manufactured according to Embodiments 1 and 2 and Comparative Example, electroluminescence (EL) characteristics have been measured by applying a forward bias direct current voltage to the light emitting elements, and the measurement results of T95 lifetime measured using a lifetime measuring device are shown in Table 1 below.

TABLE 1

| | Voltage | Blue | Efficiency | T95 | CIE | |
|---|---|---|---|---|---|---|
| | (V) | index | (cd/A) | (hr) | x | y |
| [Embodiment | 3.67 | 236 | 10.6 | 380 | 0.139 | 0.045 |
| 1] | | | | | | |
| [Embodiment | 3.64 | 225 | 10.1 | 310 | 0.139 | 0.045 |
| 2] | | | | | | |
| [Comparative | 3.62 | 225 | 10.1 | 195 | 0.138 | 0.045 |
| example] | | | | | | |

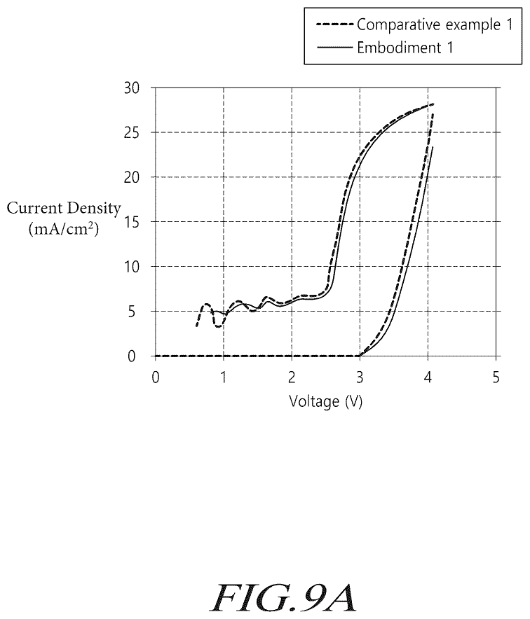

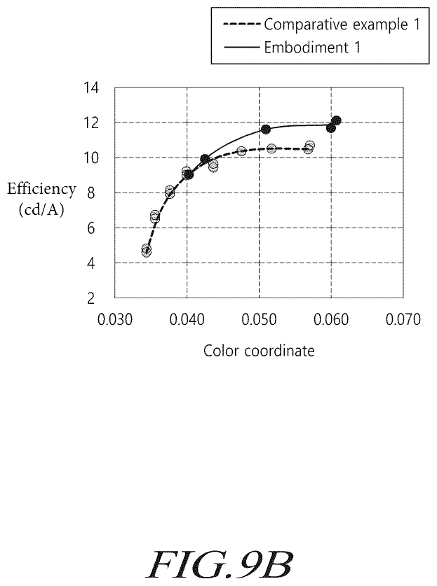

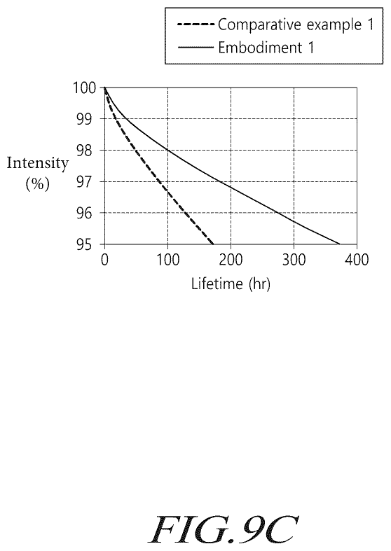

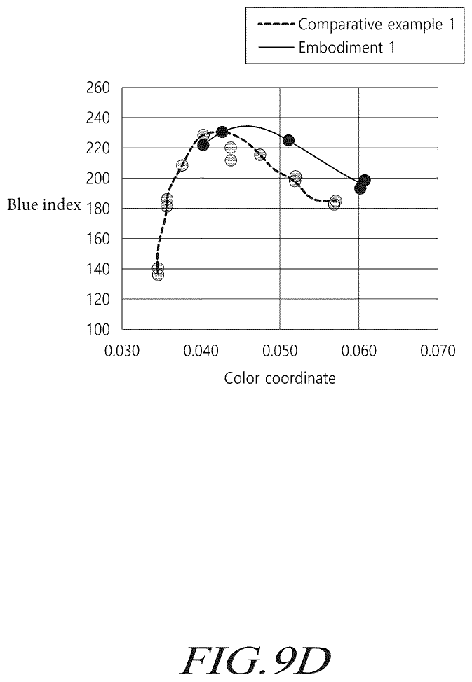

FIGS. 9A to 9D are graphs showing the results of comparing Embodiment 1 with Comparative example according to one or more embodiments of the present disclosure.

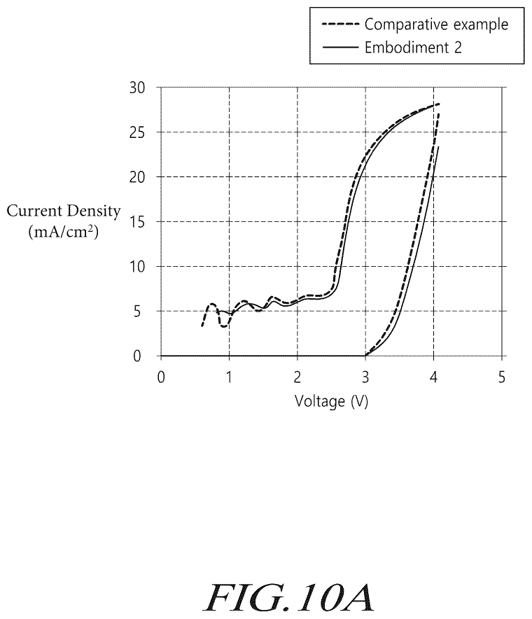

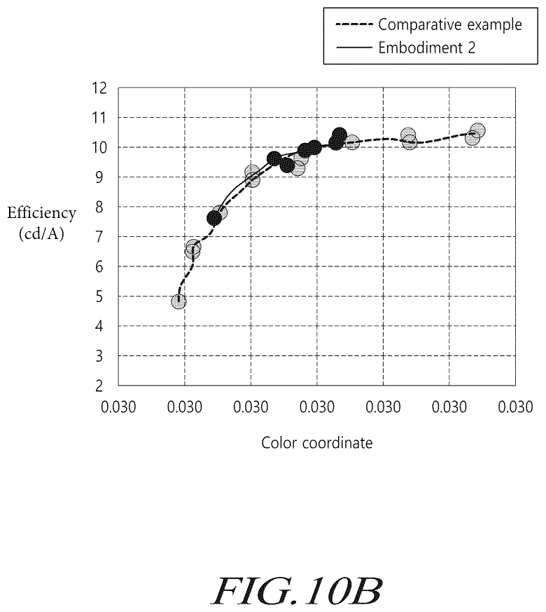

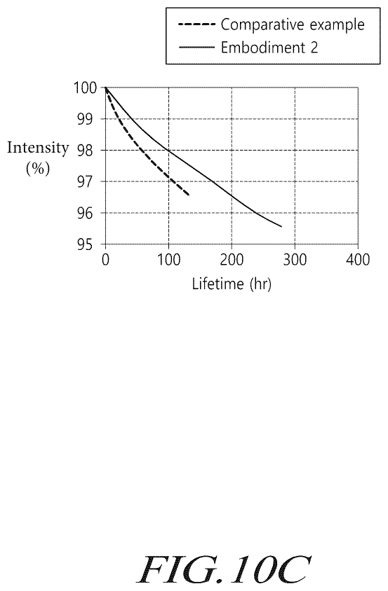

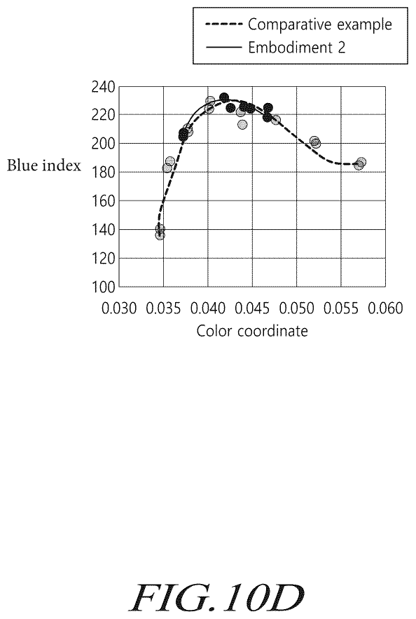

FIGS. 10A to 10D are graphs showing the results of comparing Embodiment 2 with Comparative example according to one or more embodiments of the present disclosure.

As can be seen from the results in Table 1, Embodiment 1 where the first emission layer is introduced between the electron blocking layer and the second emission layer shows increased efficiency and lifetime (T95) compared to the Comparative example.

In addition, Embodiment 2 where the first emission layer is introduced between the hole blocking layer and the second emission layer shows increased lifetime (T95) compared to the Comparative example.

The embodiments described above will be briefly described as follows.

According to the embodiments of the present disclosure, a display device can be provided that includes a substrate including a normal area configured that a plurality of first pixels are disposed therein and configured to have a first resolution, and an optical area configured that a plurality of second pixels are disposed therein and configured to have a second resolution lower than the first resolution, a first electrode layer located on the substrate, a first emission layer located on the first electrode layer and including a first host, a second emission layer located on the first emission layer, including the first host in the normal area, and including a second host different from the first host in the optical area, and a second electrode layer located on the second emission layer.

According to one or more embodiments of the present disclosure, a display device may comprise a normal area in which a plurality of first subpixels are disposed; and an optical area in which a plurality of second subpixels are disposed, wherein the number of the second subpixels per unit area in the optical area is less than the number of the first subpixels per unit area in the normal area, wherein each of the first subpixels in the normal area and the second subpixels in the optical area comprises a light emitting element, wherein the light emitting element comprises: a first electrode layer located on a substrate; one or more stacks; and a second electrode layer on the one or more stacks, wherein each of the one or more stacks comprises: a first emission layer located on the first electrode layer and comprising a first host in the normal area and in the optical area; and a second emission layer located on the first emission layer, comprising the first host in the normal area, and comprising a second host different from the first host in the optical area.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device, comprising:
a substrate comprising a normal area with a plurality of first pixels in the normal area and the normal area having a first resolution, and an optical area with a plurality of second pixels in the optical area and the optical area having a second resolution that is less than the first resolution;
a first electrode layer on the substrate;
a first emission layer on the first electrode layer, the first emission layer comprising a first host in the normal area and a first host in the optical area;
a second emission layer on the first emission layer, the second emission layer comprising the first host in the normal area and a second host, the second host different from the first host in the optical area; and
a second electrode layer on the second emission layer.

2. The display device of claim 1, wherein the first emission layer and the second emission layer in the optical area include a first dopant and a second dopant respectively, and the first dopant and the second dopant are same or different.

3. The display device of claim 2, wherein the first host and the second host are phosphorescent hosts or fluorescent hosts, and the first dopant and the second dopant are phosphorescent dopants or fluorescent dopants.

4. The display device of claim 1, wherein a sum of thicknesses of a portion of the first emission layer in the optical area and a portion of the second emission layer in the optical area are larger than a sum of thicknesses of a portion of the first emission layer in the normal area and a portion of the second emission layer in the normal area.

5. The display device of claim 1, further comprising:
a hole transport layer between the first electrode layer and the first emission layer.

6. The display device of claim 5, wherein a sum of thicknesses of the hole transport layer, a portion of the first emission layer in the normal area and a portion of the second emission layer in the normal area is a same as a sum of thicknesses of the hole transport layer, a portion of the first emission layer in the optical area and a portion of the second emission layer in the optical area.

7. The display device of claim 1, further comprising:
a third emission layer on the second emission layer, wherein the third emission layer comprises the first host in the normal area and the first host in the optical area.

8. The display device of claim 7, wherein a portion of the third emission layer in the optical area includes a third dopant that is a same or different from a first dopant and a second dopant of the first emission layer and the second emission layer.

9. The display device of claim 7, wherein a sum of thicknesses of a portion of the first emission layer in the optical area, a portion of the second emission layer in the optical area and the portion of the third emission layer in the optical area are larger than a sum of thicknesses of a portion of the first emission layer in the normal area, a portion of the second emission layer in the normal area and a portion of the third emission layer in the normal area.

10. The display device of claim 9, further comprising:
a hole transport layer between first electrode layer and the first emission layer.

11. The display device of claim 10, wherein a sum of thicknesses of a portion of the hole transport layer in the normal area, the portion of the first emission layer in the normal area, the portion of the second emission layer in the normal area and the portion of the third emission layer in the normal area is a same as a sum of thicknesses of a portion of the hole transport layer in the optical area, the portion of the first emission layer in the optical area, the portion of the second emission layer in the optical area and the portion of the third emission layer in the optical area.

12. The display device of claim 5, further comprising:
an electron blocking layer between the hole transport layer and the first emission layer; and
a hole blocking layer on the second emission layer.

13. The display device of claim 10, further comprising:
an electron blocking layer between the hole transport layer and the first emission layer; and
a hole blocking layer on the third emission layer.

14. The display device of claim 12, wherein an Equation 1 is satisfied in the optical area, or at least one of an Equation 2 or an Equation 3 is satisfied:
the Equation 1 defined as T₁<T₂<T_{HB},
wherein, in the Equation 1, T_{HB} is a triplet state energy level of the hole blocking layer, T₁ is a triplet state energy level of the first emission layer, and T₂ is a triplet state energy level of the second emission layer,
the Equation 2 defined as L_{HB}<L₂<L₁,
wherein, in the Equation 2, L_{HB} is a lowest unoccupied molecular orbital (LUMO) energy level of the hole blocking layer, L₁ is a LUMO energy level of the first emission layer, and L₂ is a LUMO energy level of the second emission layer,
the Equation 3 defined as |H₂−H₁|≤0.1 eV,
wherein, in the Equation 3, H₁ is a highest occupied molecular orbital (HOMO) energy level of the first emission layer, and H₂ is a HOMO energy level of the second emission layer.

15. The display device of claim 14, wherein a thickness of the second emission layer is equal to or more than 2 nm and less than or equal to 5 nm.

16. The display device of claim 12, wherein an Equation 4 is satisfied in the optical area, or at least one of an Equation 5 or an Equation 6 is satisfied:
the Equation 4 defined as T₂<T₁<T_{EB},
wherein, in the Equation 4, T_{E}B is a triplet state energy level of the electron blocking layer, T₁ is a triplet state energy level of the first emission layer, and T₂ is a triplet state energy level of the second emission layer,
the Equation 5 defined as L₂<L₁<L_{EB},
wherein, in the Equation 5, L_{E}B is a lowest unoccupied molecular orbital (LUMO) energy level of the electron blocking layer, L₁ is a LUMO energy level of the first emission layer, and L₂ is a LUMO energy level of the second emission layer,
the Equation 6 defined as H₂<H₁<H_{EB},
wherein, in the Equation 6, H_{EB} is a highest occupied molecular orbital (HOMO) energy level of the electron blocking layer, H₁ is a HOMO energy level of the first emission layer, and H₂ is a HOMO energy level of the second emission layer.

17. The display device of claim 16, wherein a thickness of the first emission layer is equal to or more than 2 nm and less than or equal to 5 nm.

18. The display device of claim 13, wherein, an Equation 7 and an Equation 8 are satisfied in the optical area, or at least one of an Equation 9, an Equation 10, an Equation 11 and an Equation 12 is satisfied:
the Equation 7 defined as T₁>T₂,
the Equation 8 defined as T₃>T₂,
wherein, in the Equation 7 and the Equation 8, T₁ is a triplet state energy level of the first emission layer, T₂ is a triplet state energy level of the second emission layer, and T₃ is a triplet state energy level of the third emission layer,
the Equation 9 defined as T_{EB}>T₁>T₂,
wherein, in the Equation 9, T₁ is a triplet state energy level of the first emission layer, T₂ is a triplet state energy level of the second emission layer, and T_{EB} is a triplet state energy level of the electron blocking layer,
the Equation 10 defined as T_{HB}>T₃>T₂,
wherein, in the Equation 10, T₂ is a triplet state energy level of the second emission layer, T₃ is a triplet state energy level of the third emission layer, and T_{HB} is a triplet state energy level of the hole blocking layer,
the Equation 11 defined as L₁>L₂,
wherein, in the Equation 11, L₁ is a lowest unoccupied molecular orbital (LUMO) energy level of the first emission layer, and L₂ is a LUMO energy level of the second emission layer,
the Equation 12 defined as H₁>H₂,
wherein, in the Equation 12, H₁ is a highest occupied molecular orbital (HOMO) energy level of the first emission layer, and H₂ is a HOMO energy level of the second emission layer.

19. The display device of claim 18, wherein a thickness of each of the first emission layer and the third emission layer is equal to or more than 2 nm and less than or equal to 5 nm.

20. A display device, comprising:
a normal area including a plurality of first subpixels; and
an optical area including a plurality of second subpixels,
wherein a number of the plurality of second subpixels per unit area in the optical area is less than a number of the plurality of first subpixels per unit area in the normal area,
wherein each of the plurality of first subpixels in the normal area and the plurality of second subpixels in the optical area comprises a light emitting element,
wherein the light emitting element comprises:
a first electrode layer on a substrate;
one or more stacks; and
a second electrode layer on the one or more stacks,
wherein each of the one or more stacks comprises:
a first emission layer on the first electrode layer, the first emission layer comprising a first host in the normal area and a first host in the optical area; and
a second emission layer on the first emission layer, the second emission layer comprising the first host in the normal area and a second host, the second host different from the first host in the optical area.
